(19) United States
(12) Patent Application Publication
(10) Pub. No.: US 2021/0274597 A1
(43) Pub. Date: Sep. 2, 2021

(54) Transformer for Tankless Water Heater

(71) Applicant: Van Zeitz, (US)

(72) Inventors: Van Zeitz, Stanton, CA (US); Bradford Dean Peeters, Costa Mesa, CA (US)

(73) Assignee: Van Zeitz, Stanton, CA (US)

(21) Appl. No.: 16/840,388

(22) Filed: Apr. 5, 2020

Related U.S. Application Data
(60) Provisional application No. 62/983,697, filed on Mar. 1, 2020.

(51) Int. Cl. H05B 1/02; F24D 19/00; F24H 1/10; F24H 9/00; F24H 9/20; H05B 3/82; H05K 1/16; H01F 17/00

(52) U.S. Cl. CPC H05B 1/0283; F24D 19/0097; F24H 1/103; H01F 17/0013; F24H 9/2028; H05B 3/82; H05K 1/165; F24H 9/0015

(57) ABSTRACT

A tankless hot water heater has a molded body having an inlet and an outlet. The water heater has a clamshell design such that upper and lower portions are removably attached to one another. A channel extends from the inlet to the outlet. Heating elements extend through at least a portion of the channel and are configured to heat water flowing through the channel. Sensors are configured to measure temperature of water flowing through the channel prior to coming into contact with the heating element. Sensors measure flow rates, temperatures, presence of air, and/or other factors. A controller adjusts power supplied to heating elements using data from sensors. The controller can be on a printed circuit board that has a current transformer formed from one or more printed coils adjacent to a trace.

### RELATED APPLICATION

This application claims the benefit of U.S. Provisional Patent Application Ser. No. 62/983,697, filed Mar. 1, 2020 and entitled “TANKLESS MOLDED WATER HEATER CIRCUIT BOARD,” which is incorporated by reference herein.

### BACKGROUND

Traditional water heaters produce heated water and store it in an insulated tank until the hot water is needed. As the tank can only keep the water heated for a limited time, unused hot water must periodically be reheated so that it is ready for use.

Tankless water heaters have been developed to eliminate the need for a storage tank. Water is heated on demand. Numerous designs of tankless water heaters have been introduced. Many of these designs are somewhat complex, including tubing, couplings, and other separate parts.

Heat generated in a tankless water heater may be controlled with a system that includes sensors and a controller. The controller may be on a printed circuit board that includes a current transformer.

What is needed is a simpler tankless water heater design with fewer parts that are conveniently accessible. What is also needed is a simpler current transformer design.

### BRIEF SUMMARY OF THE INVENTION

In one embodiment of the invention, a tankless hot water heater has a molded body having an inlet and an outlet that are in fluid communication with one another. A channel extends from the inlet to the outlet. At least one heating element extends through the channel to heat water. An optional sensor may be configured to measure the temperature of water flowing through the channel prior to coming into contact with the heating element. The heater has at least one flow sensor configured to measure flow and/or flow rate of water prior to coming into contact with the heating element. At least one sensor is configured to measure temperature of water flowing through the channel after coming into contact with the heating element(s).

The heater has a controller, which may include a microprocessor, adapted to control heat generated by the heating element based on input from the temperature and flow sensors. Optionally, the controller may be on a printed circuit board. The printed circuit board may include a current transformer formed with one or more printed coils on the circuit board. In designs with at least two printed coils, some or all of the printed coils may be wired in series. The coil(s) are positioned adjacent to a printed circuit board trace. A circuit board having a transformer formed from one or more printed coils may be used in conjunction with any of the tankless water heater designs, as well as with other water tankless water heaters or water heaters that have a tank.

Also, the molded body may be a clamshell design having an upper portion and a lower portion, with the upper and lower portions removably secured together.

The tankless hot water heater as described above may include various optional features, either alone or in combination. The channel may include at least two straight portions interconnected by a curved portion, with first and second heating elements extending through first and second straight portions, respectively. The controller may independently control heat generated by the first and second heating elements. The channel may include grooves molded in the water channel adapted to create turbulent flow. The grooves may be twisted, and extend into the wall. As an alternative, twisted protrusions may extend from the wall. The channel may have both portions with grooves and smooth portions to achieve a desired flow profile.

In the clamshell design, a portion of the channel may be molded into each of the upper and lower portions of the clamshell, wherein the channel becomes closed when the upper and lower portions are secured together. The water heater may have a display unit for displaying water temperature and/or other information such as time of day, flow rate, inflow & outflow temperature, and other data as desired. The system may include an input device for receiving desired temperature settings from a user. The input may be manual, electronic, via an app on a mobile phone, or any other manner in which data can be input. The heater may optionally be connected to a network, such as a local network and/or the Internet.

Continuing with optional features that may be incorporated into the tankless water heater, either alone or in combination with other optional features, the water heater may have a pressure relief valve. The controller may include a microprocessor and memory, and may be programmed to use an algorithm, tables, and data as suitable for controlling the heating elements.

The heater element, such as a coil for example, may be in direct contact water. The channel may include a series of generally straight portions interconnected with curved portions, the straight and curved portions being molded into the body. In this configuration, heating elements may extend in respective generally straight portions of the channel.

The body may be injection molded, or otherwise molded. Typically, the body is a molded thermoset polymer suitable for use with the hot water the heater generates.

According to another embodiment of the present invention, a tankless, on-demand hot water heater has an injection molded body with a water inlet and a water outlet that are in fluid communication with one another. A channel extends from the inlet to the outlet, the channel having at least two molded straight portions interconnected by a molded curved portion. Heating elements extend through respective straight portions. Sensors are configured to measure temperature and flow of water entering the heater. One or more sensors are positioned to measure temperature of water exiting the heater. Sensors of various types may be employed at various positions within the heater. For instance, sensors to detect the presence of air in the channel may be employed.

The system includes a controller comprising a microprocessor adapted to control heat generated by the heating elements independently from one another, based on input from temperature and flow sensors. The molded body may be a design having an upper portion and a lower portion that are separable from one another, with the upper and lower portions removably secured together. The channels may include twisted grooves molded into the water channel and adapted to create turbulent flow.

According to another embodiment of the invention, a tankless hot water heater has a molded body having an inlet and an outlet that are in fluid communication with one another via a channel. At least one heating element extends through at least a portion of the channel and is configured to heat water flowing through the channel. At least one sensor is configured to measure at least one of water temperature and water flow at a location in the channel. A controller is adapted to control heat generated by the at least one heating element based on input from the at least one sensor. The molded body has an upper portion and a lower portion, with an upper portion of the channel molded into the upper portion of the molded body and a lower portion of the channel molded into the lower portion of the molded body, the upper and lower portions of the body being removably secured together.

Another embodiment relates to a printed circuit board that has a controller and a current transformer formed from at least two printed coils wired in series and located adjacent to a trace. Such a printed circuit board may optionally be used in conjunction with any of the foregoing tankless water heater embodiments, to control heat generated within the heater and/or other variables within the water heater, or may be used for purposes other than water heaters. The circuit board may optionally have a controller adapted to amplify the signal from the coils and/or an amplifier.

The foregoing and other objects, features, and advantages of the invention will become more apparent from the following detailed description, which proceeds with reference to the accompanying figures.

### BRIEF DESCRIPTION OF THE DRAWINGS

FIG. 1 is a top view of an assembled tankless water heater with the enclosure cover removed;

FIG. 2 is a top view of the tankless water heater within a metal base, with the circuit board removed for clarity;

FIG. 3 is the tankless water heater of FIG. 1 with the upper and lower portions of the molded body separated;

FIG. 4 illustrates the upper portion of the water heater of FIG. 1;

FIG. 5 illustrates the lower portion of the water heater of FIG. 1;

FIG. 6 illustrates an end view of the water heater of FIG. 1 with the circuit board in place;

FIG. 7 illustrates an assembly of a metal base, water heater, and top cover with a screen on the cover for displaying information;

FIG. 8A-C illustrate components of a system including a metal base, a water heater, circuit board, and a cover with a display screen;

FIG. 9 illustrates one embodiment of an air transformer built into a printed circuit board; and

FIG. 10 illustrates one embodiment of printed coils on either side of a trace, with non-limiting dimensions provided as one example.

### DETAILED DESCRIPTION OF A PREFERRED EMBODIMENT

Considering one embodiment of the present invention in general terms, the invention includes an injection molded tankless on-demand water heater. The heater has a clamshell design that enables various water passage shapes, sizes, and contours, all incorporated into one two-piece heat-exchanger unit that does not utilize multiple separate tubes and/or manifolds. This embodiment includes a combination of smooth bore and twisting grooves which are molded into the water passages to enable laminar flow where desired, or turbulent flow where desired.

The heater includes multiple heating elements made of nickel-chromium wire with which the water comes in direct contact with the heating elements. Each of the heating elements may be individually controlled such that failure of one heating element may affect system performance but has no impact on the individual performance of the remaining heating elements.

This embodiment may have further features, such as a pressure relief valve and/or a high temperature cut-out switch.

The heater includes a control system. In one embodiment, the control system includes a paddle-wheel style flow meter, with multiple imbedded magnets, and which includes a moving device allowing for variable flow increased low-flow sensitivity and also high flow rates when device moves. A Hall Effect sensor detects pulses per second from the paddle-wheel magnets. Alternatively, other flow sensors that detect flow and/or flow rate may be used.

The control system may also include temperature sensors at the outflow and/or inflow regions of the heater. The control system may also include sensing when there is air in the system. For example, capacitance water sensing may be employed and the control system adapted to prevent energizing the heating elements when air is detected in the water passages.

The control system may include a printed circuit board that has a microprocessor. As the unit may be used with a variety of voltage inputs, in one embodiment the power supply is adapted to receive input at a variety voltages, such as between 120 VAC to 300 VAC, for example. The control system may also have automatic voltage sensing to the heating elements and used to control system performance. Similarly, it may have automatic current sensing to the heating elements and used to control system performance.

The system may have certain user-control features. For instance, it may have a user selectable “Soft Start” to avoid dimming or flickering of household lighting. It may have user selectable power-draw from 100% down to 50% power (Amps) in 1% increments. In one embodiment, the system has 10 color LEDs providing service technicians with 10 system status indications.

The system may also have digital communication links that enables balancing of work load between heat exchangers when more than one heat exchanger is used in series. In some embodiments, the heater has a digital LCD display that provides the user system status messages, error codes per unit, and/or menu items. In one embodiment, multiple error codes are generated to allow faults to be identified down to the component level.

Numerous other options and features may be incorporated into the system. For instance, the system and/or display may have multi-color backlighting to enhance viewing and to draw attention to status messaging. Set-Point temperature and actual output temperature may be displayed simultaneously, for example. The display may also display such information as fluid temperature at various locations within the heater, paddle wheel pulses per second converted to gallons per minute (GPM), hours of operation, date, time of day, temperature history, energy use, water used over a chosen period of time, and any other information that may be of interest to a user and/or support professionals.

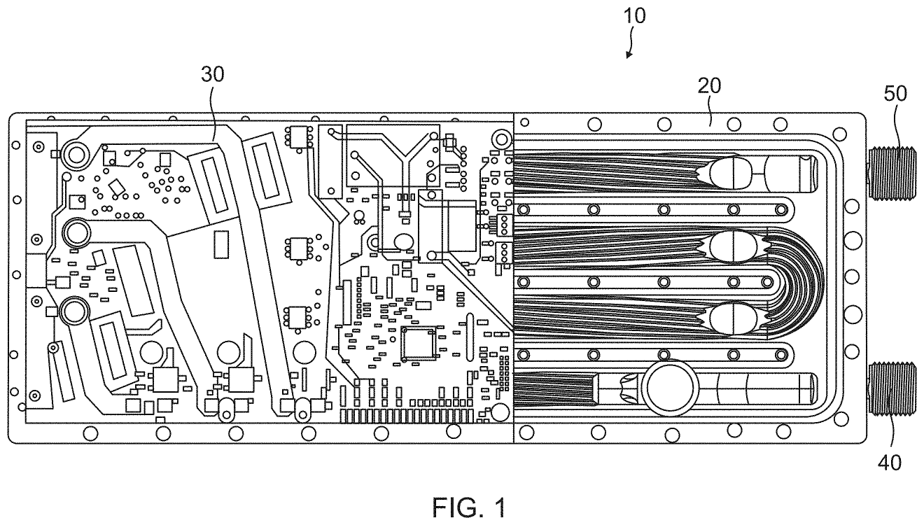

Turning now to one specific embodiment of the invention in FIG. 1, a tankless electric water heater 10 (with the cover removed for clarity) has an injection-molded, clamshell body 20. The injection-molded body is typically formed from a strong, durable, heat-resistant polymer that is suitable for long-term use with electric heating elements and high-temperature water flowing through channels therein. Other forms of molding known in the art may alternatively be employed, or other manufacturing methods such as 3-D printing.

A circuit board 30 is secured to one side of the clamshell body 20. The circuit board includes a microprocessor. The circuit board 30 receives signals from sensors such as flow sensors, temperature sensors, air sensors and/or other sensors. Based on these inputs, the microprocessor controls aspects of the heater, such as the power supplied to heating elements within the body 20. The microprocessor is suitably programmed with code, can access tables, data and the like to execute its functions.

Water flows into the heater at inflow fitting 40. The water then flows through a serpentine channel within the molded body, contacting heating elements as it flows, then exits through outflow fitting 50.

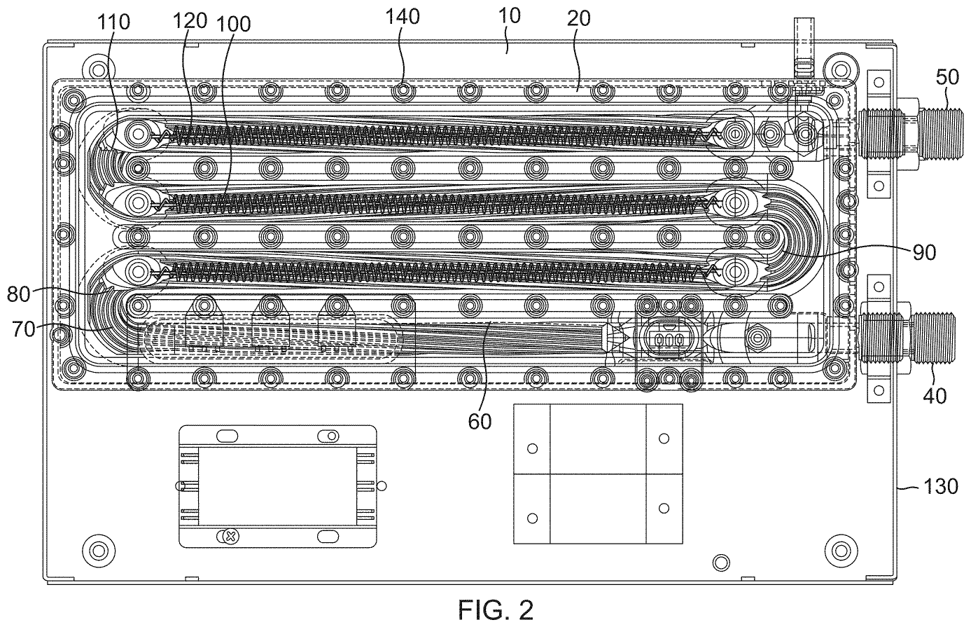

FIG. 2 illustrates the body 20 with the cover and circuit board removed to view the interior of the body. The body is held within a metal base 130, which may alternatively be made of other materials known in the art. As noted, the heater has a water inlet 40 and a water outlet 50. A series of channels runs through the interior of the body, through which water flowing through the body flows. The channels comprise straight portions 60, 80, 100, 120 and integral curved portions 70, 90, 110. Heating elements extend through straight portions. In the embodiment of FIG. 2, there are three heating coils, extending through straight channel portions 80, 100, 120, respectively. The upper and lower portions of the clamshell design are held together with fasteners such as screw or nuts at numerous locations, one of which is illustrated as reference numeral 140.

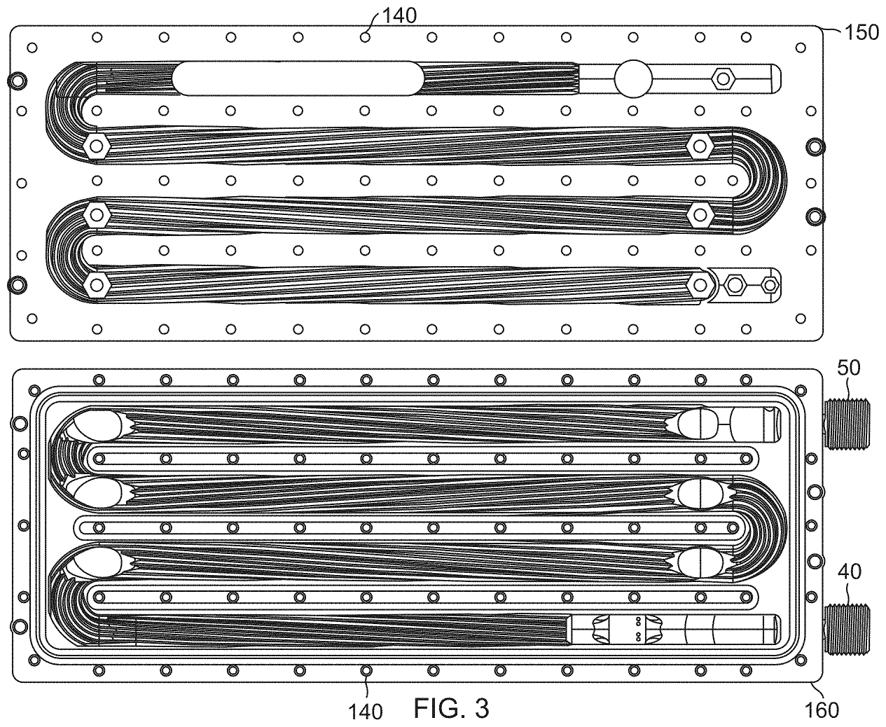

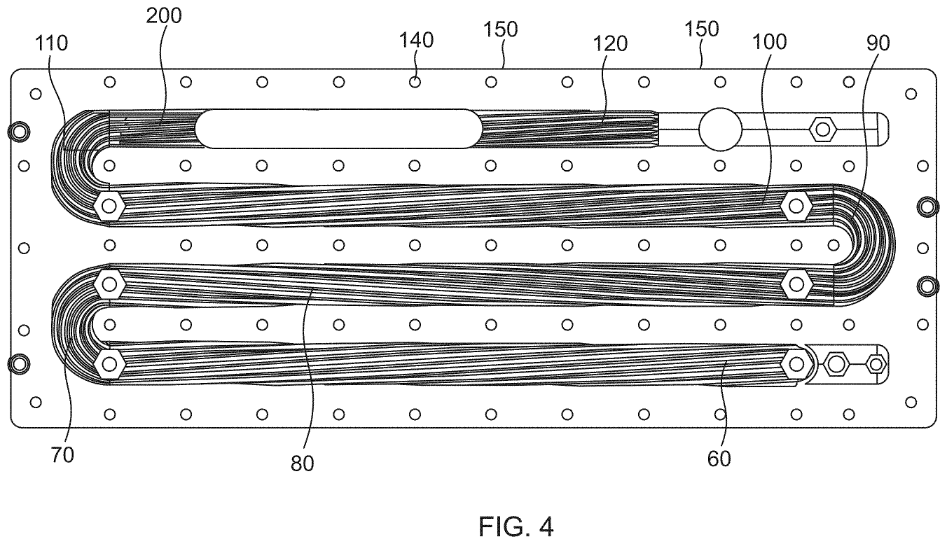

FIG. 3 illustrates the interior of the top 150 and bottom 160 of the heater, as they appear when uncoupled and with the molded channel facing upwardly. As can be seen, this embodiment includes a combination of smooth bore and twisting grooves 200 (FIG. 4) which are molded into the water passages to enable laminar flow where desired, or turbulent flow where desired. As seen in FIG. 3, the top and bottom portions include complementary portions of water channels and twisting grooves. The heating elements, which are typically metal coils, extend through straight channel portions 80, 100, 120 on the top portion 150 of the heater, as seen in FIG. 2. The ends of each coil are secured at screw heads (seen on FIG. 2 but not numbered).

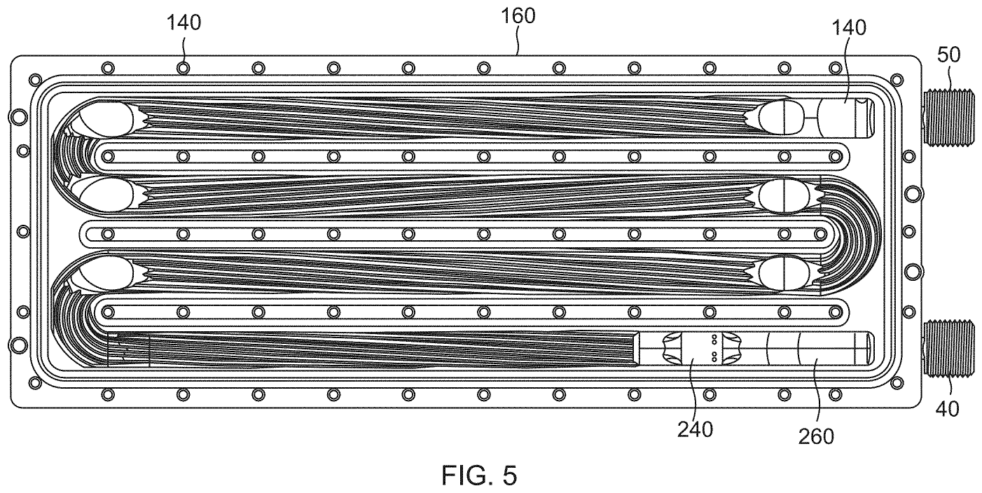

FIGS. 4 and 5 illustrate the top and bottom portions of the heater, respectively, in greater detail. Referring to FIG. 5, the bottom portion 160 also includes temperature sensors 240 and 250 at the inflow and outflow portions, respectively. There is also a flow sensor 260 at the inflow location. The various sensors are in communication with the circuit board 30 which, as noted, controls power supplied to each of the heating element coils 80, 100, 120 via a microprocessor.

Typically the top and bottom portions of the clamshell are secured together with screws, bolts and/or other fasteners suitable for tightly securing the two portions together such that water is contained within the unit and does not leak. Waterproof rings, seals, and the like may be employed as desired to further prevent water from leaking from the unit.

Portions of the channel may be made deeper than others. For example, the channel may be deeper at the inlet and outlets. This accommodates inlet and outlet ports that have a greater diameter than other portions of the channel. That is, most of the channel through which water flows may have a narrower diameter while the channel at the inlet and outlet portions may have a wider diameter, tapering or otherwise narrowing from the wider diameter to the narrower diameter. The dimensions of the channel within the body may vary at certain points, either as a result of molding considerations or to alter the profile of the water flow.

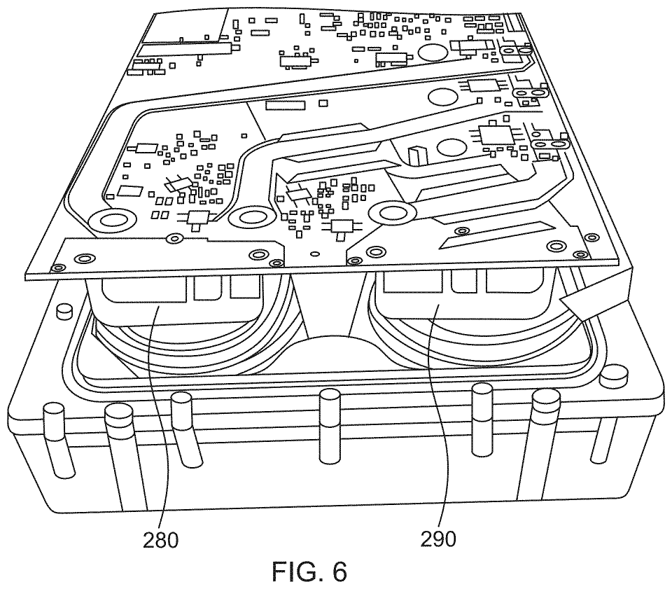

Considering FIG. 6, capacitance plates such as 280 and 290 may be provided to detect when air is present in the channel. Damage to the unit can be caused by the presence of air in the system because no water is present to cool the heating elements(s). Signals from the capacitance plates may be transmitted to the microprocessor, which controls the application of power to the heating element(s) in response to the presence of air.

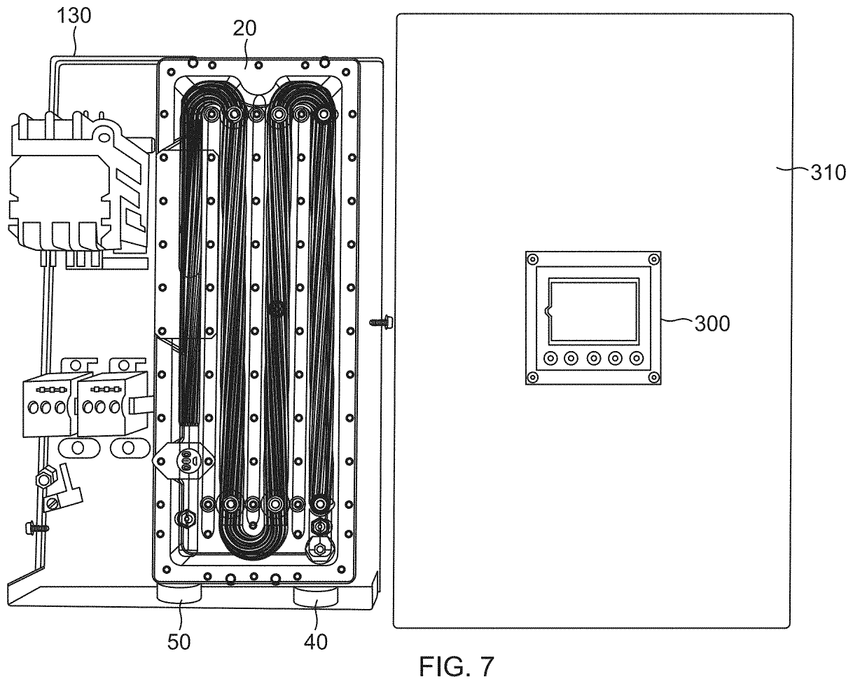

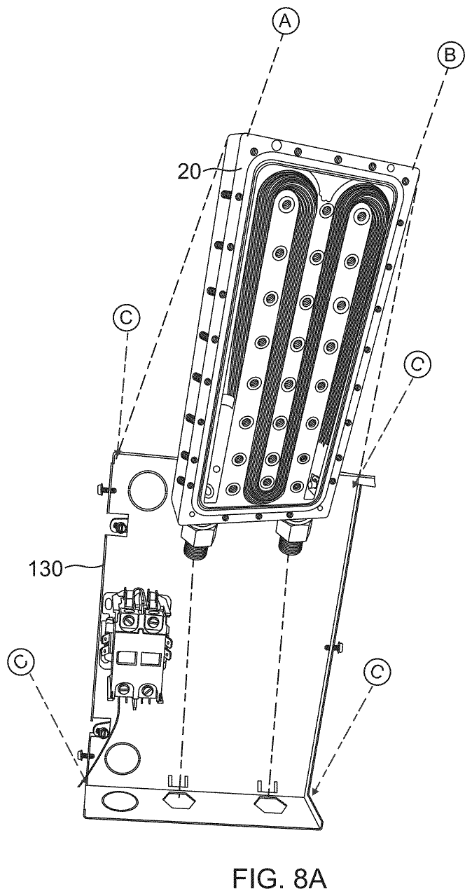

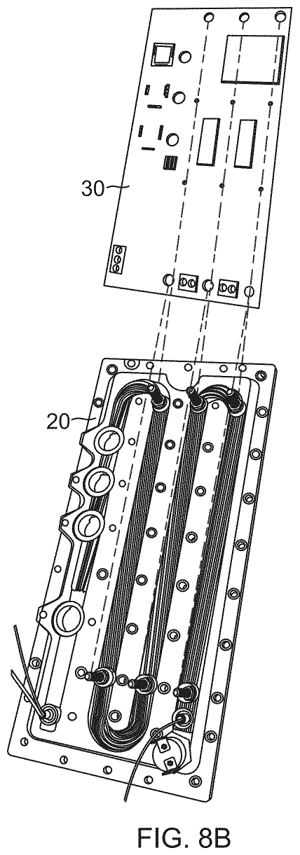

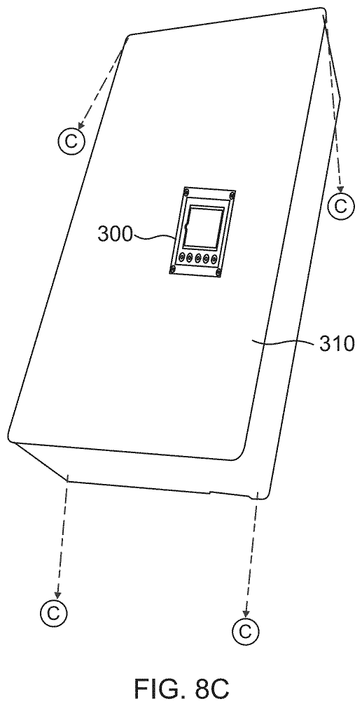

An LCD display 300 is illustrated in FIG. 7 as a feature on the exterior of a cover 310 (see also FIG. 8C). The display 300 may display any of a wide variety of information that may be of interest to a user, technician, or others. For instance, the system and/or display may have multi-color backlighting to enhance viewing and to draw attention to status messaging. Set-Point temperature and actual output temperature may be displayed simultaneously, for example. The display may also display such information as fluid temperature at various locations within the heater, gallons per minute (GPM) of water flow, hours of operation, date, time of day, temperature history, energy use, water used over a chosen period of time, and any other information that may be of interest to a user and/or support professionals.

FIGS. 8A-C illustrate, in exploded view components of the system. In FIG. 8A, the water heater body fits into a metal steel base 130, with inlet and outlet ports extending through openings in the base 130. FIG. 8B illustrates the circuit board 30 fitting atop the water heater body 20. FIG. 8C illustrates the cover 310 with LCD screen 300 on the exterior, fitting over the assembly such that corners C slide down onto location C on the metal base (FIG. 8A).

Considering alternative embodiments, the heater may be used in several configurations. In the first configuration, a single water heater heats an entire house or apartment on demand, without having to store pre-heated water in a tank. In another, two or more units may be interconnected to increase the heating ability. In one embodiment, the heaters are connected with stainless steel flex-hose in a 2, 3, or 4 unit daisy-chain arrangement. In yet another variation, individual heating units may be located near areas where hot water is used, such as adjacent to showers, dishwashers, clothes washers, and the like.

In operation of a preferred embodiment, water flows into the inflow port. The flow sensor detects that water is flowing. A temperature sensor determines the temperature of the water flowing into the water heater. As the water flows, it encounters the molded twisting grooves, which increase the turbulence of the flow. The water then flows across one or more heating coils which, preferably, the water contacts directly. The microprocessor takes input from various sensors to determine how much power to provide to the heating elements. The power may be increased or decreased in order to achieve the desired output temperature, which the user may input. On exit from the heater, a temperature sensor determines the temperature of the exiting water to ensure that the heater is meeting the outflow water temperature target. If the water is too hot or too cold, the microprocessor adjusts power supplied to the heating coils until the water exiting the unit is within a desired temperature range.

Considering one alternative embodiment of the circuit board 30 (FIG. 1), the board 30 may include a digital controller. As one example, one such controller is the Microchip dsPIC33EV256GM006 Digital Signal Controller (DSC).

The controller can be adapted to facilitate a range of diagnostic capabilities with respect to a tankless water heater. In one embodiment, low-cost circuitry is implemented to monitor voltage across, and current through, each of the heating elements so that software can detect and announce faults such as shorted or open triacs or broken heating elements via the user interface, for example.

Each voltage monitoring circuit converts the instantaneous voltage across a heating element into a frequency that is transmitted through an optical isolator to the dsPIC DSC as a pulse train. The monitoring circuit starts running at 20 volts and continues to increase in frequency as the voltage increases up to 400 volts, giving the dsPIC DSC a picture of the line-voltage waveform using its capture/compare on-chip peripherals while keeping it safely isolated from the high voltages involved.

The voltage-to-frequency converter circuits were designed for reliability at low cost, not for linearity, on the premise a non-linearity would be compensated using an algorithm that is easily supported by the dsPIC DSC's processing power.

One embodiment of the present invention includes a technique for monitoring current through each of the triac/heating-element circuits. A common approach to line-voltage current sensing is to use a small current-sense resistor in series with the line and a special chip intended to amplify the small voltage drop across the current-sense resistor while tolerating the large common-mode voltages. This would then be converted to a digital signal to be sent across the isolation barrier to the dsPIC DSC in a manner similar to the voltage monitor circuit.

While the voltage monitor circuit described above is self-powered, the chip that amplifies the signal from the current-sense resistor typically requires a power supply. It would be desirable to have a design that eliminates or reduces the need for a power supply.

An alternative is a current transformer or a Hall-effect sensor that provides an MCU-compatible signal voltage while at the same time providing isolation from the line voltage. However, these are expensive components.

A solution we have developed is to create a current transformer using a printed circuit board (PCB) trace and one or more printed coils adjacent to the trace, essentially creating an air transformer built into the PCB itself.

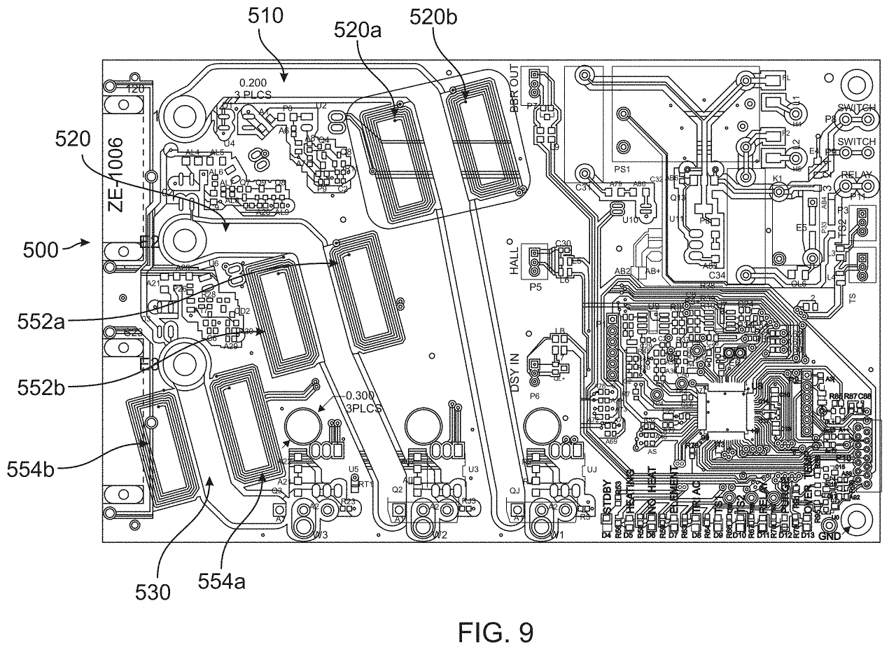

Referring to the embodiment of FIG. 9, the PCB 500 includes three traces 510, 520, and 530. In electronics, a signal trace on a printed circuit board is the equivalent of a wire for conducting signals. Each trace consists of a flat, narrow part of typically copper foil that remains after etching.

Etched coils 550a,b, 552a,b, and 554a,b reside on respective sides of and adjacent to each trace. When AC power is transmitted through a PCB trace, a voltage is induced into the two etched coils on either side of the trace. For example, power flowing through trace 510 induces voltage into etched coils, 550a and 550b. The amount of current flowing through the trace can be sensed by measuring the induced voltage from the coils. This approach replaces components that otherwise would be mounted on the PCB.

With no ferrous material to enhance the inductive coupling, the on-chip op amps in the dsPIC DSC may be used to strengthen the signal. By implementing a second stage of gain between the external amplifier chip and the on-chip ADC, the demands on the external chip may be reduced, allowing for a more robust design with better margins.

The DSP power of the dsPIC DSC makes it possible to monitor and combine voltage and current waveforms in real time to determine Root Mean Square (RMS) power. Using information from the flow monitor and the water inlet and outlet temperature sensors, sophisticated control algorithms can use a combination of feedback and feed-forward techniques to maximize performance which, for a water heater, means coming up to temperature quickly, while minimizing overshoot and maximizing safety. The dsPIC DSC's ability to do this while running a complex user interface and a daisy-chained serial communication protocol for adding on more slave units provides many options for maximizing flexibility in various installations.

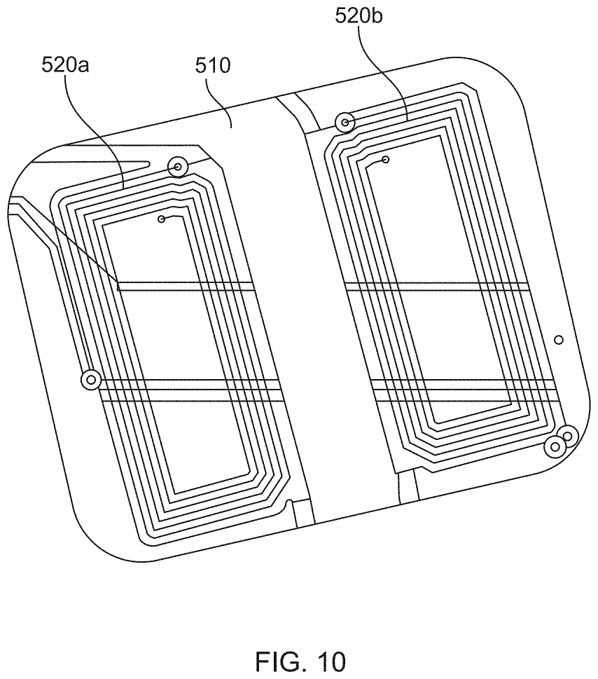

FIG. 10 illustrates one non-limiting example of dimensions in one embodiment of the PCB “air coils.” A challenge is getting sufficient signal strength. By using two similar coils wired in series, via traces on the bottom side of the PCB for example, the signal voltage may be doubled. In an alternative embodiment, a single coil on one side of the main trace may be used, so long as sufficient signal strength is obtained.

In accordance with Maxwell's Laws of Electromagnetism, the strength of the signal is proportional to the area of the pick-up coil and falls off in proportion to its distance from the conductor being sensed. One loop of a coil defines an area enclosed by that loop. The signal picked up by that loop is proportional to that area. By using multiple loops, the signal from each loop adds to the resulting signal.

Due to the single-layer nature of a PCB conductor, multiple loops are wound in a spiral pattern. As the loops get smaller and smaller, they contribute less to the signal output until a point is reached where it is not worthwhile to continue making more loops.

In principle, the width of the conductors and the spacing between them may be reduced to increase the number of loops in the available space in order to obtain as large a signal as desired. In practice, the width and spacing of conductors on a PCB is limited by the technology level used in its fabrication. In one non-limiting design presented as an example, a 10-mil trace, 10-mil space design is used for ease of manufacture and cost-efficiency.

To maximize signal strength, the loops may be made as large as possible in the available space on the PCB and placed as close as possible to the current-carrying trace without violating regulatory spacing requirements for the voltages involved. The size of the current-carrying trace itself may be a function of the maximum current the product is designed to handle. It is noted that the difficulty of capturing and processing the output signal becomes significantly greater as the size decreases substantially.

It is to be understood that the specific dimensions in the embodiment of FIG. 10 are illustrative of one particular, non-limiting design. Adjustments may be made within the scope of the invention for a particular design at hand. The number of coils and the symmetry or asymmetry of the positioning of the coils may be varied in alternative designs. Also, it is within the scope of the invention to use a single coil so long as sufficient signal strength can be achieved.

As seen in the drawings, the unit may include various other components, such as a relay and power distribution blocks. The unit is typically housed within an enclosure, which may be made of steel or other material.

Specific exemplary embodiments of the present invention may have various features. In one embodiment, a digital control allows a user to select a set-point between 70F and 140F, with a factory default setting of approximately 110F or 120F. Of course, these settings and ranges may be altered for specific uses.

In a presently preferred embodiment, water will flow regardless of what temperature it has reached. There is no valve in the heater of this embodiment to control flow. The only other “valve” in this example system is a UL Required Pressure Relief Valve that will open at 150 psi, for example, to bleed off pressure. In alternative embodiments, a control valve may be incorporated at a desired location and controlled by a microprocessor based on inputs from sensors.

To sense incoming water flow, a paddle wheel style flowmeter may be placed within 3-4 inches of the water inlet, for example. In one type of flowmeter, a small plastic flapper forces the water across a paddle wheel during very low-flow situations to overcome small flow-rates in which there is not enough water-flow to make the paddle wheel move. Water flow at higher volumes easily moves the paddle wheel, as the plastic flapper moves out of the way. Alternatively, other types of flow sensors that detect flow and/or flow rate may be used.

Although in the preferred embodiment the heater heats water, it may be adapted to heat other fluids. Depending on the fluid, adjustments may need to be made, such as ensuring that the material of the heating element is compatible with the fluid to be heated. The present invention may also be adapted for use in extreme cold or heat environments, underwater, or in other specialized environments. In such cases, the housing in which the heater resides may include insulation or other means to protect the heater from the external conditions, for instance.

As used herein, the term “upper” and “lower” are relative terms. For example, upper and lower portions of the clamshell unit may be side-by-side in some configurations. Consequently, “upper” and “lower” are not directionally limiting.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

What is claimed is:

1. A tankless hot water heater comprising:
a molded body having an inlet and an outlet that are in fluid communication with one another;
a channel extending from the inlet to the outlet;
at least one heating element extending through at least a portion of the channel and configured to heat water flowing through the channel;
at least one sensor configured to measure temperature of water flowing through the channel prior to coming into contact with the at least one heating element;
at least one sensor configured to measure flow of water flowing through the channel prior to coming into contact with the at least one heating element; and
at least one sensor configured to measure temperature of water flowing through the channel after coming into contact with the at least one heating element; and
a printed circuit board comprising a controller adapted to control heat generated by the at least one heating element based on input from the temperature and flow sensors;
the printed circuit board including a current transformer formed with printed coils on the circuit board that are wired in series and positioned adjacent to a printed circuit board trace;
wherein the molded body is a clamshell design having an upper portion and a lower portion, with the upper and lower portions removably secured together.

2. A tankless water heater as defined in claim 1, wherein the channel comprises at least two straight portions interconnected by a curved portion, with first and second heating elements extending through first and second straight portions, respectively.

3. The tankless water heater as defined in claim 2, wherein the controller independently controls heat generated by the first and second heating elements.

4. A tankless water heater as defined in claim 1, wherein the channel comprises grooves molded in the water channel adapted to create turbulent flow.

5. A tankless water heater as defined in claim 1, wherein the water heater comprises a display unit for displaying water temperature, heater performance data, heater diagnostic data, and/or user selectable inputs.

6. A tankless water heater as defined in claim 8, wherein the water heater includes an input device for receiving desired temperature settings from a user.

7. A tankless water heater as defined in claim 1, wherein the controller comprises a microprocessor and memory.

8. A tankless water heater as defined in claim 1, wherein the heater element comprises a coil that is in direct contact with water.

9. A tankless water heater as defined in claim 1, wherein the flow sensor is a flow rate sensor.

10. A tankless hot water heater comprising:
a molded body having an inlet and an outlet that are in fluid communication with one another via a channel;
at least one heating element extending through at least a portion of the channel and configured to heat water flowing through the channel;
at least one sensor configured to measure at least one of water temperature and a water flow characteristic at a location in the channel;
a printed circuit board having a controller adapted to control heat generated by the at least one heating element based on input from the at least one sensor;
wherein the molded body has an upper portion and a lower portion, with the channel molded into the upper portion of the molded body and/or molded into the lower portion of the molded body, the upper and lower portions of the body being removably secured together; and
wherein the printed circuit board includes a current transformer formed with at least one printed coil adjacent to a circuit board trace.

11. A tankless water heater as defined in claim 10, wherein the channel comprises at least two molded straight portions interconnected by a molded curved portion, with first and second heating elements extending through first and second straight portions, respectively.

12. The tankless water heater as defined in claim 11, wherein the controller controls heat generated by each of a plurality of heating elements independently from one another.

13. A tankless water heater as defined in claim 10, wherein the channel comprises grooves molded in the water channel adapted to create turbulent flow.

14. A tankless water heater as defined in claim 10, wherein the flow characteristic is a flow rate.

15. A tankless water heater as defined in claim 10, wherein an upper portion of the channel is molded into the upper portion of the molded body a lower portion of the channel is molded into the lower portion of the molded body.

16. A tankless water heater as defined in claim 10, wherein the heater further comprises a cover with a display screen visible from an exterior of the cover.

17. A water heater comprising:
a water heater having at least one heating element;
a controller on a printed circuit board, the controller adapted to control heat generated by the at least one heating element based on input from at least one sensor;
wherein the printed circuit board includes a current transformer that has at least one printed coil adjacent to a circuit board trace.

18. A tankless water heater as defined in claim 17, wherein the printed circuit board comprises at least two printed coils wired in series and located adjacent to a trace.

19. A tankless water heater as defined in claim 17, wherein the printed circuit board comprises an amplifier adapted to amplify a signal from the coils.

20. A tankless water heater as defined in claim 17, wherein the water heater has a plurality of heating coils and the controller individually controls each of the heating coils.
